(19) United States
(12) Patent Application Publication
(10) Pub. No.: US 2008/0129281 A1
(43) Pub. Date: Jun. 5, 2008

(54) Method and apparatus for magnetic field sensor calibration

(75) Inventor: Michael Lemp, Rancho Santa Margarita, CA (US)

Correspondence Address: Crockett & Crockett, Suite 400, 24012 Calle De La Plata, Laguna Hills, CA, 92653, US

(73) Assignee: Yamcon, Inc.

(21) Appl. No.: 11/607,293

(22) Filed: Nov. 30, 2006

(51) Int. Cl. G01R 35/00

(52) U.S. Cl. 324/202

(57) ABSTRACT

The methods and devices provide for calibration of two or three-axis magnetic field sensors with an artificial magnetic calibration field, or a sequence of magnetic calibration fields, that overwhelm the earth's magnetic field and any other extraneous magnetic fields that may be present in the calibration area. The calibration field or fields are produced with a known relationship to the test stand or jig on which a two and or three-axis magnetic field sensor is secured. The calibration fields are oriented to produce fields that have generally parallel lines of force (relative to the sensor to be calibrated) with minimal curvature or discontinuity. For each coil or calibration field, data from each sensor may be collected and analyzed to enable one or more correction factors to be determined for each sensor. The correction factors may be provided to the apparatus in which the magnetic sensor is secured to correct sensor data and provide more accuracy.

### FIELD OF THE INVENTIONS

The inventions described below relate to the field of magnetic sensor calibration, and more specifically to methods and apparatus for calibrating two-axis and or three-axis magnetic field sensors for use in celestial object locators.

### BACKGROUND OF THE INVENTIONS

Calibration of magnetic field sensors intended for detection of the magnetic field of the earth may be performed using the earth's magnetic field as a reference. However the presence of structural steel, electrical wiring and motors as in buildings and factories significantly disrupts the earth's magnetic field, and may generate additional magnetic fields and yield imprecise results.

What is needed are methods and apparatus for producing one or more stable and predictable magnetic fields that may be used to calibrate two and or three-axis magnetic field sensors.

### SUMMARY

The methods and devices described below provide for calibration of multi-axis sensors such as two or three-axis magnetic field sensors with an artificial magnetic calibration field, or a sequence of magnetic calibration fields, that overwhelm the earth's magnetic field and any other extraneous magnetic fields that may be present in the calibration area. The calibration field or fields are produced with a known relationship to the test stand or jig on which a two and or three-axis magnetic field sensor is secured. The calibration fields are oriented to produce fields that have generally parallel lines of force (relative to the sensor to be calibrated) with minimal curvature or discontinuity. For each coil or calibration field, data from each sensor may be collected and analyzed to enable one or more correction factors to be determined for each sensor. The correction factors may be provided to the apparatus in which the magnetic sensor is secured to correct sensor data and provide more accuracy.

In an alternative technique, a single magnetic field source may be used and the sensor jig may enable two or three degrees of freedom to orient the sensor jig and the sensor secured thereon in two or three orthogonal positions to perform the necessary calibration of the sensor. For example, the x-direction sensor may be calibrated with the sensor jig in a first position with the X-sensor oriented parallel to the calibration field. To calibrate the y-sensor the jig may be oriented 90° from the first position into a second position to place the y-sensor parallel to the calibration field. If a third sensor axis is available it may be calibrated by orienting the sensor jig 90° from both the first and second positions into a third position with the Z-axis sensor oriented parallel to the calibration field. At each position, data from each sensor may be collected and analyzed to enable one or more correction factors to be determined for each sensor. The correction factors may be provided to the apparatus in which the magnetic sensor is secured to correct sensor data and provide more accuracy.

### BRIEF DESCRIPTION OF THE DRAWINGS

FIG. 1 is a perspective view of a celestial object location device having magnetic field sensors interacting with the magnetic field of the earth.

FIG. 2 is a perspective view of a three-dimensional magnetic field sensor oriented relative to a viewing axis.

FIG. 3 is a perspective view of a three-dimensional magnetic field sensor in magnetic calibration fields.

### DETAILED DESCRIPTION OF THE INVENTIONS

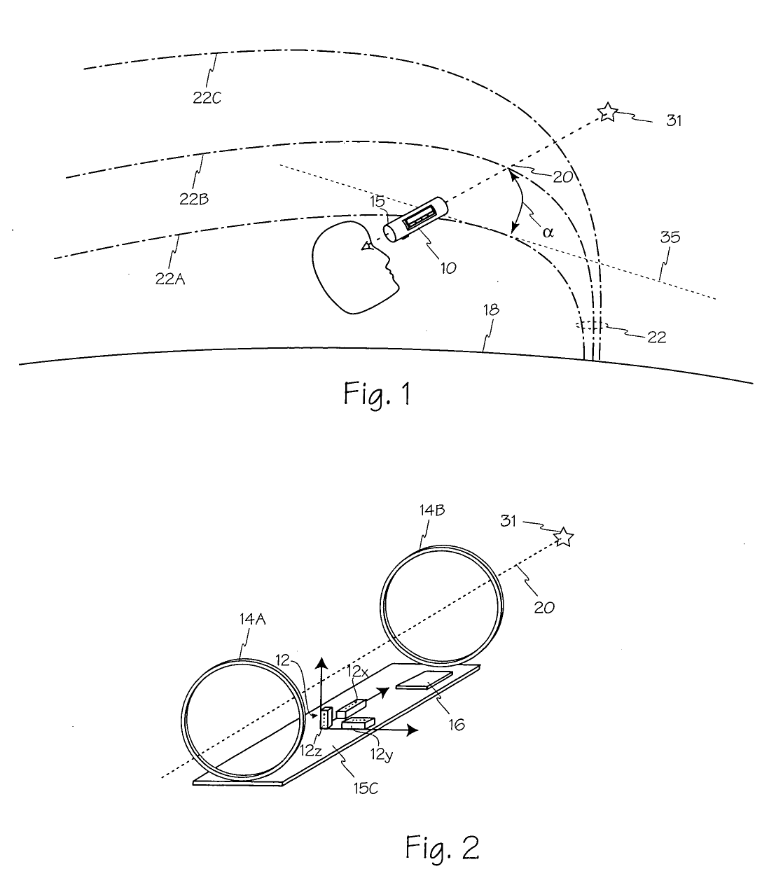

Celestial object locating device 10 of FIG. 1 includes electronics 15 oriented relative to viewing axis 20. A two or three-axis magnetic field sensor incorporated in electronics 15 may be used to determine one or more angles such as angle a relative to magnetic field 22 of earth 18. At most locations on the earth a user will encounter magnetic field lines of force such as lines 22A, 22B and 22C that are generally parallel.

Electronics 15 may include one or more subassemblies such as board 15C and microprocessor 16 of FIG. 2. Subassembly 15C may include a two or three-axis magnetic field sensor such as three-axis sensor 12. Sensor 12 includes three sub-elements 12X, 12Y and 12Z. The orientation of each sub-element to the other sub-elements and to the viewing axis may be calibrated and offset parameters determined for each sub-assembly.

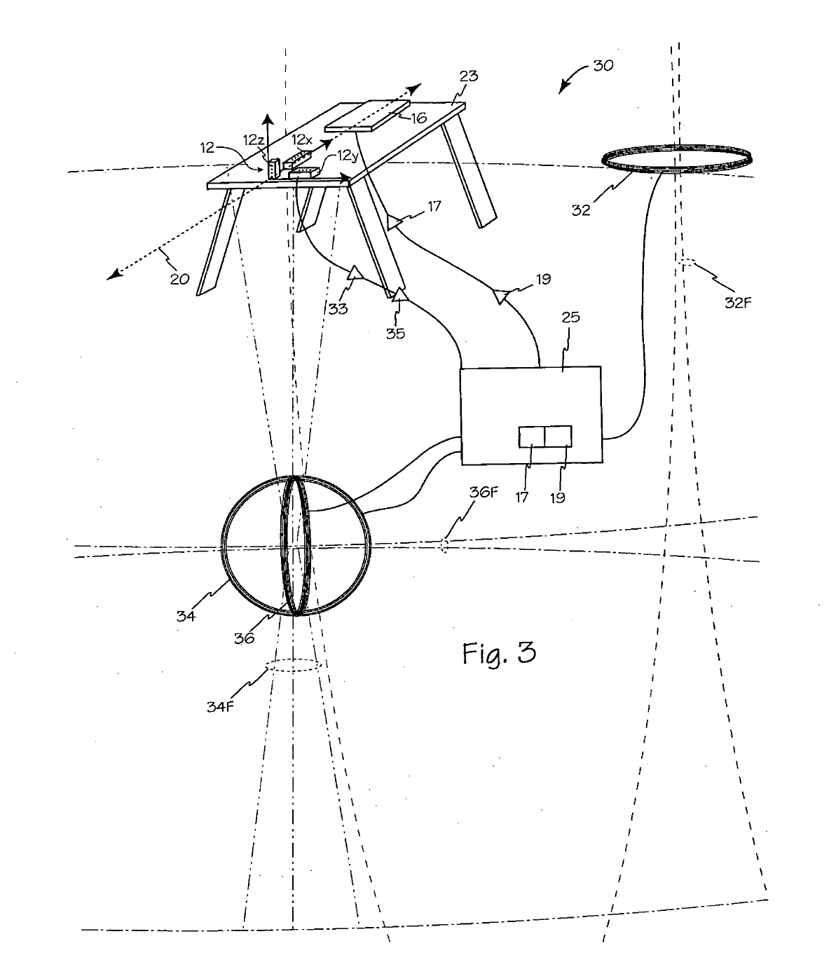

Calibration system 30 of FIG. 3 includes field generators 32, 34 and 36 which generate magnetic calibration fields 32F, 34F and 36F respectively. Calibration system 30 is controlled by controller 25 which initiates the application of each magnetic calibration field and collects orientation data 33 from each sensor sub-element. Orientation data 33 is the output of each sensor sub-element that indicates the orientation of viewing axis 20 relative to the applied calibration field. Orientation data 33 may be used to determine correction factors 17 that may be applied to orientation data 33 to enable microprocessor 16 to correct orientation data 33 to accurately determine the real orientation of viewing axis 20 relative to the earth's magnetic field.

Controller 25 may also vary the intensity of each applied magnetic calibration field to collect field strength data 35. Field strength data 35 may be used by controller 25 to generate field strength correction factors 19 that may be used by microprocessor 16 to correct field strength data 35 to accurately determine the real orientation of viewing axis 29 relative to the earth's magnetic field.

While the preferred embodiments of the devices and methods have been described in reference to the environment in which they were developed, they are merely illustrative of the principles of the inventions. Other embodiments and configurations may be devised without departing from the spirit of the inventions and the scope of the appended claims.

1. A device for calibration of a multiaxis magnetic sensor comprising:
a test stand engaging an electronic assembly including a multiaxis magnetic field sensor;
a first magnetic field generator oriented to produce a first magnetic field at the test stand;
a second magnetic field generator oriented to produce a second magnetic field at the test stand, the second magnetic field orthogonal to the first magnetic field;
a third magnetic field generator oriented to produce a third magnetic field at the test stand, the third magnetic field orthogonal to the first and second magnetic fields;
a controller for controlling the first, second and third magnetic field generators and the electronic assembly on the test stand, the controller monitoring the multi-axis magnetic field sensor and producing one or more correction factors to be provided to the electronic assembly.
